(19) United States
(12) Patent Application Publication
(10) Pub. No.: US 2010/0329482 A1
(43) Pub. Date: Dec. 30, 2010

(54) AUDIO DIGITAL TO ANALOG CONVERTER AND AUDIO PROCESSING APPARATUS INCLUDING THE SAME

(76) Inventor: Yong-Hee LEE, Yongin-si (KR)

Correspondence Address: F. CHAU & ASSOCIATES, LLC, 130 WOODBURY ROAD, WOODBURY, NY, 11797, US

(21) Appl. No.: 12/761,468

(22) Filed: Apr. 16, 2010

(30) Foreign Application Priority Data
Jun. 26, 2009 (KR) 10-2009-0057347

(51) Int. Cl. H03G 3/00; H03M 1/66

(52) U.S. Cl. 381/104; 341/144

(57) ABSTRACT

An audio DAC includes a delta/sigma modulator (DSM), a pulse width modulator (PWM) and an output unit. The DSM delta-sigma modulates an over-sampled digital signal to generate a multi-bit quantization signal. The PWM pulse width modulates the multi-bit quantization signal to generate a single-bit pulse width modulation signal. The output unit includes an analog filter that low-pass filters the single-bit pulse width modulation signal to generate an analog output signal.

### CROSS-REFERENCE TO RELATED APPLICATIONS

This application claims priority under 35 USC §119 to Korean Patent Application No. 2009-0057347, filed on Jun. 26, 2009 in the Korean Intellectual Property Office (KIPO), the disclosure of which is incorporated by reference in its entirety herein.

### BACKGROUND

1. Technical Field

Exemplary embodiments of the inventive concept relate to audio devices, and more particularly to an audio digital/analog converter and an audio processing apparatus including the same.

2. Discussion of Related Art

Delta sigma modulation (DSM) is a technique for obtaining high signal resolutions using noise shaping and over-sampling. Noise shaping frequency-shifts quantization noise generated in a signal-band during signal quantization into a no-signal band (i.e., a band that is not used). The amount of noise frequency-shifted into the no-signal band is proportional to a loop filter order of a modulator.

Over-sampling is a process of sampling a signal with a frequency significantly higher than twice the bandwidth of the signal. Since the frequency band is extended by the over-sampling, the level of quantization noise is decreased. As the over-sampling frequency is increased (i.e., an over-sampling ratio (OSR)), the level of the quantization noise is decreased, so that a signal-to-noise-and-distortion ratio (SDNR) in the bandwidth is increased. Accordingly, the SDNR may be increased in the bandwidth of a signal by using the over-sampling and the noise shaping in a DSM device.

In a digital/analog converter, a switched-capacitor filter (SCF) may be used for decreasing the quantization noise that is frequency-shifted into the no-signal band and for converting audio signals in the signal-band to analog signals. However, the SCF includes many switches and capacitors, and thus the SCF occupies a large area, consumes a large amount of power, and generate a large amount of noise. Further, in systems that use multiple channels such as digital televisions and DVDs, a number of SCFs corresponding to the number of channels may be included therein, which may result in an even larger area and power consumption.

### SUMMARY

According to an exemplary embodiment of the inventive concept, an audio DAC includes a delta/sigma modulator (DSM), a pulse width modulator (PWM) and an output unit. The DSM delta-sigma modulates an over-sampled digital signal to generate a multi-bit quantization signal. The PWM pulse width modulates the multi-bit quantization signal to generate a single-bit pulse width modulation signal. The output unit includes an analog filter that low-pass filters the single-bit pulse width modulation signal to generate an analog output signal.

The PWM may be a symmetric-type PWM or an asymmetric-type PWM. When the PWM is an asymmetric-type PWM, the audio DAC may further include an error correction circuit, connected between the DSM and the PWM, which corrects errors generated by the PWM. The error correction circuit may be connected in an open loop between the DSM and the PWM. The error correction circuit may include a delayer delaying the multi-bit quantization signal and an adder adding the multi-bit quantization signal and an output of the delayer.

The output unit may further include a switching circuit that selectively connects a first reference voltage and a second reference voltage to the analog filter in response to the single-bit pulse width modulation signal.

The audio DAC may further include a clock generator which generates a first clock signal and a second clock signal having a higher frequency than a frequency of the first clock signal. The first clock signal may be provided to the DSM, and the second clock signal may be provided to the PWM. The frequency of the second clock signal may be K times as high as the frequency of the first clock signal, where K is a positive integer equal to or greater than two.

The PWM may includes a ramp signal generator that generates a triangular ramp signal swinging between a first peak value and a second peak value based on the second clock signal and a comparator that compares the multi-bit quantization with the ramp signal to provide the pulse width modulation signal having a pulse width varying according to a level of the multi-bit quantization signal, in synchronization with the second clock signal.

The audio DAC may further include an over-sampler that over-samples a digital input signal to generate the over-sampled digital signal. The DSM may include a subtracter that subtracts the multi-bit quantization signal from the over-sampled digital signal, a loop filter that filters an output signal of the subtracter and a quantizer that quantizes an output signal of the loop filter to provide the multi-bit quantization signal. An operating frequency of the PWM may be higher than an operating frequency of the DSM.

According to an exemplary embodiment of the inventive concept, a multi-channel audio digital-to-analog converter (DAC) includes a plurality of channels, each converting corresponding digital input signal to a corresponding analog output signal and a clock generator that multiplies a reference clock signal to generate a multiplied clock signal and output the multiplied clock signal to each pulse width modulator PWM included in each of the channels. Each of the channels includes a delta sigma modulator DSM that quantizes the corresponding digital input signal which is over-sampled to generate a multi-bit quantization signal, a PWM that pulse width modulates the corresponding multi-bit quantization signal to generate a single-bit pulse width modulation signal, and an output unit including an analog filter that low-pass filters the corresponding single-bit pulse width modulation signal to generate the corresponding analog output signal.

The clock generator may be shared by the plurality of channels. The PWM may be one of a symmetric type PWM or an asymmetric type PWM. When the PWM is asymmetric, the multi-channel audio DAC may further include an error correction circuit connected in an open loop between the DSM and the PWM, and configured to correct errors generated by the PWM. The error correction circuit may be configured to be isolated from being influenced by or influencing transfer characteristics of a feedback circuit of the DSM.

According to an exemplary embodiment of the inventive concept, an audio processing apparatus includes a volume control unit and an audio digital to analog convert (DAC). The volume control unit volume-controls audio source data to generate digital data in response to a volume control signal. The audio DAC over-samples the digital data, and converts the over-sampled digital data to an analog output signal. The audio DAC includes a delta/sigma modulator (DSM), a pulse width modulator (PWM) and an output unit. The DSM delta-sigma modulates the over-sampled digital data to generate a multi-bit quantization signal. The PWM pulse width modulates the multi-bit quantization signal to generate a single-bit pulse width modulation signal. The output unit includes an analog filter that low-pass filters the single-bit pulse width modulation signal to generate the analog output signal.

The volume control unit may further include a volume table outputting a volume value in response to the volume control signal and a multiplier that multiplies the audio source data by the volume value to generate the digital data.

### BRIEF DESCRIPTION OF THE DRAWINGS

Exemplary embodiments of the inventive concept will be more clearly understood from the following detailed description taken in conjunction with the accompanying drawings.

FIG. 1 is a block diagram illustrating an audio digital/analog converter (DAC) according to an exemplary embodiment of the inventive concept.

FIG. 2 is a block diagram illustrating an example of a DSM in FIG. 1 according to an exemplary embodiment of the inventive concept.

FIG. 3 is a block diagram illustrating an example of a PWM in FIG. 1 according to an exemplary embodiment of the inventive concept.

FIG. 4A is a waveform illustrating an exemplary symmetric pulse width modulation signal, and FIG. 4B is a waveform illustrating an exemplarly asymmetric pulse width modulation signal.

FIG. 5 is a block diagram illustrating an audio DAC according to an exemplary embodiment of the inventive concept.

FIG. 6 is a block diagram illustrating an example of an error correction circuit of FIG. 5 according to an exemplary embodiment of the inventive concept.

FIG. 7A is a circuit diagram illustrating an example of an output unit in FIG. 1 according to an exemplary embodiment of the inventive concept.

FIG. 7B is a circuit diagram illustrating an example of the output unit in FIG. 1 according to an exemplary embodiment of the inventive concept.

FIG. 8A is a graph illustrating an exemplary relationship between an OSR and a transfer function.

FIG. 8B is a graph illustrating an exemplary relationship between a quantization level and a transfer function.

FIG. 8C is a graph illustrating an exemplary relationship between an OSR, a quantization level, and a transfer function.

FIG. 9 is a block diagram illustrating a multi-channel audio DAC according to an exemplary embodiment of the inventive concept.

FIG. 10 is a block diagram illustrating an audio processing apparatus according to an exemplary embodiment of the inventive concept.

### DETAILED DESCRIPTION OF EXEMPLARY EMBODIMENTS

Exemplary embodiments of the inventive concept will be described more fully hereinafter with reference to the accompanying drawings. The present inventive concept may, however, be embodied in many different forms and should not be construed as limited to the exemplary embodiments set forth herein. In the drawings, like numerals refer to like elements throughout. It will be understood that when an element is referred to as being “connected” or “coupled” to another element, it can be directly connected or coupled to the other element or intervening elements may be present

FIG. 1 is a block diagram illustrating an audio digital/analog converter (DAC) according to an exemplary embodiment of the inventive concept. Referring to FIG. 1, an audio DAC 10 includes a delta sigma modulator (DSM) 100, a pulse width modulator (PWM) 200 and an output unit 300. The audio DAC 10 may further include an over-sampler (OS) 20 and a clock generator (CG) 30.

The over-sampler 20 over-samples a digital signal (DS) to generate an over-sampled digital signal ODS. The digital signal (DS) may have been generated from sampling an analog audio signal at a predetermined sampling rate. The DSM 100 delta-sigma modulates the over-sampled digital signal ODS to generate a multi-bit quantization signal (MQS). The PWM 200 pulse-width modulates the multi-bit quantization signal (MQS) to generate a single-bit pulse width modulation signal PWS. The output unit 300 may include an analog filter that filters the single-bit pulse width modulation signal PWS to generate an analog output signal OUT. The clock generator 30 generates a first clock signal CLK1 and a second clock signal CLK2 based on a reference clock signal RCLK. A frequency of the second clock signal CLK2 may be twice as high as a frequency of the first clock signal CLK1.

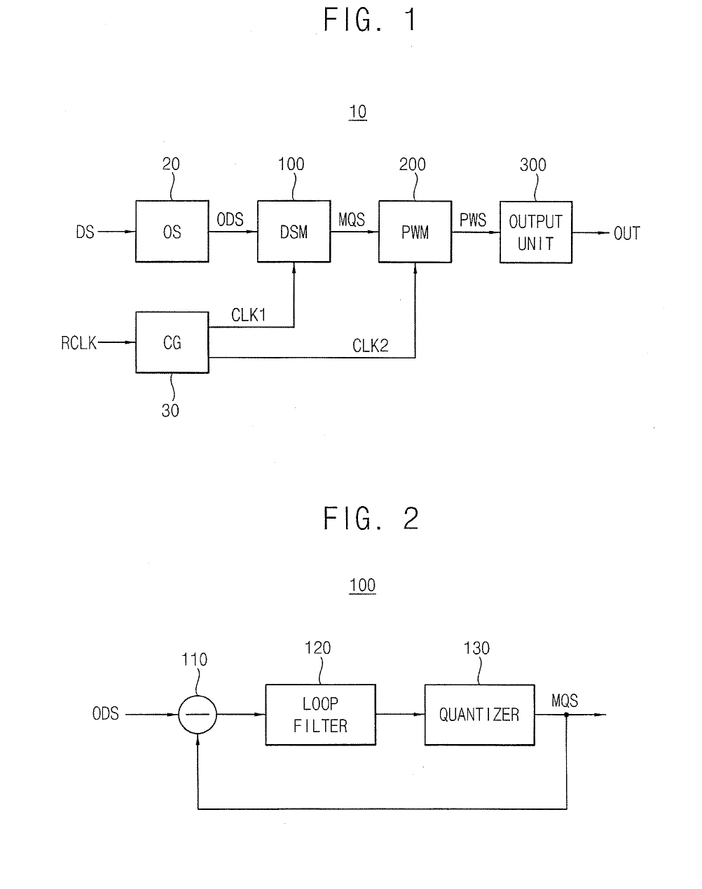

FIG. 2 is a block diagram illustrating an example of the DSM in FIG. 1 according to an exemplary embodiment of the inventive concept. Referring to FIG. 2, the DSM 100 includes a subtracter 110, a loop filter 120 and a quantizer 130. The quantizer 130 may be a multi-bit quantizer. The subtracter 110 subtracts the multi-bit quantization signal MQS from the over-sampled digital signal ODS. The loop filter 120 filters an output signal of the subtracter 110. The quantizer 130 quantizes an output signal of the loop filter 120 into an M-bit signal, where M may be a positive integer greater than or equal to two. For example, the quantizer 130 generates the multi-bit quantization signal MQS.

The output signal MQS of DSM 100 may be expressed in a Z-domain by equation 1 as follows:

MQS(z)=ODS(z)+(1−z⁻¹)^{N}*E1(z) [Equation 1],

where N is the order of the loop filter 120, and E1 (z) is quantization noise of the DSM 100.

Referring again to FIG. 1, the PWM 200 varies the width of pulses according to the level of the multi-bit quantization signal MQS for modulations. For example, a period of the multi-bit quantization signal MQS is divided into a first half period and a second half period based on a center of the pulse width modulation signal PWS. The PWM 200 performs pulse width modulation during the first half period and during the second half period to generate the pulse width modulation signal PWS as a symmetric type signal, which is symmetric with respect to the center of the period of pulse width modulation signal PWS. For example, the PWM 200 may be a symmetric type PWM. Alternately, the PWM 200 may perform pulse width modulation during the first half period differently from the second half period to generate the pulse width modulation signal PWS as an asymmetric type signal, which is asymmetric with respect to the center of the period of pulse width modulation signal PWS. For example, the PWM 200 may be an asymmetric type PWM.

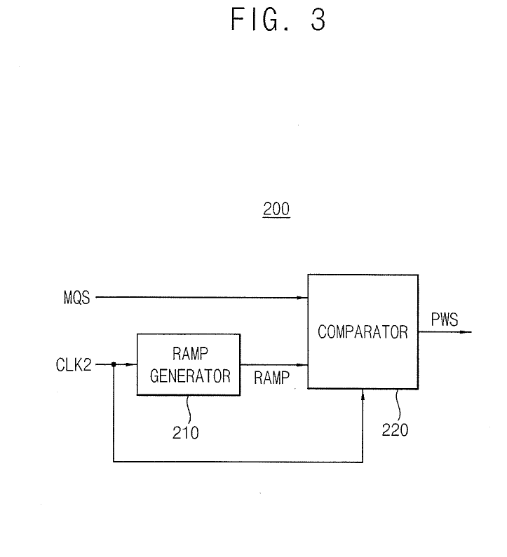

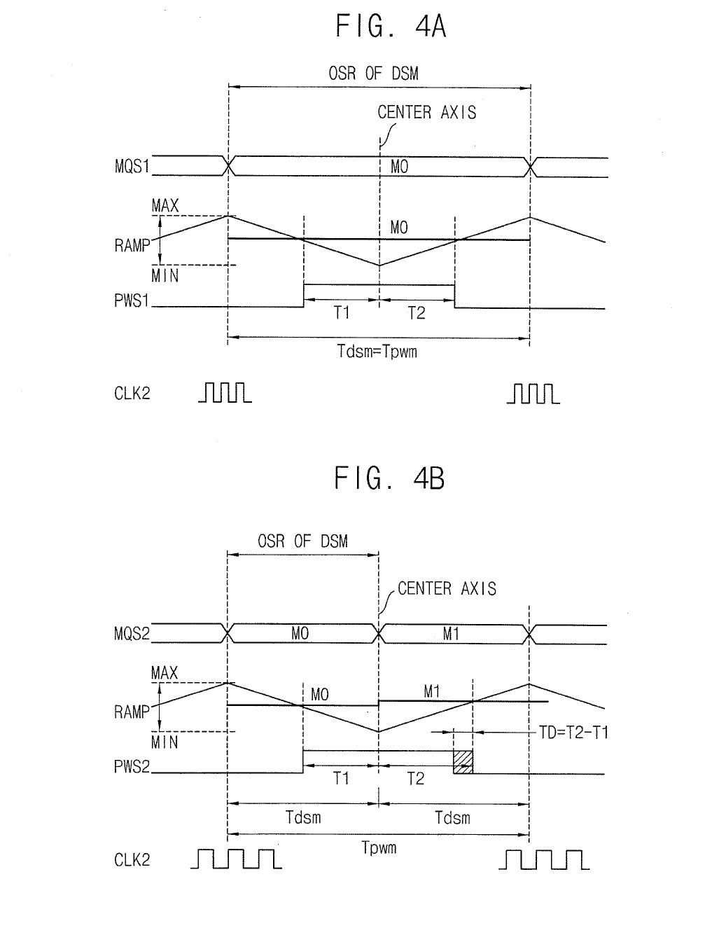

FIG. 3 is a block diagram illustrating an example of the PWM in FIG. 1 according to an exemplary embodiment of the inventive concept. FIG. 4A is a waveform illustrating an exemplary symmetric pulse width modulation signal, and FIG. 4B is a waveform illustrating an exemplary asymmetric pulse width modulation signal. Referring to FIGS. 3 to 4B, the PWM 200 includes a ramp signal generator 210 and a comparator 220.

The ramp signal generator 210 generates a triangular ramp signal RAMP, which swings between a first peak value MAX and a second peak value MIN, based on the second clock signal CLK2. A frequency of the second clock signal CLK may correspond to a variable K (e.g., where K is a positive integer greater than or equal to two) times as high as a frequency of the first clock signal CLK1, which is provided to DSM 100. The variable K may be proportional to the over-sampling rate and quantization bits of the DSM 100. Therefore, an operation frequency of the PWM 200 may be higher than an operation frequency of the DSM 100.

As illustrated in FIG. 4A, a full period Tdsm of the multi-bit quantization signal MQS1 is equal to a full period of the ramp signal RAMP, and a full period Tpwm of the pulse width modulation signal PWS1. Accordingly in FIG. 4A, a level Mo of the multi-bit quantization signal MQS1 does not change during the full period of the ramp signal RAMP. Consequently in FIG. 4A, the pulse width modulation signal PWS1 generated by comparing the multi-bit quantization signal MQS1 with the ramp signal RAMP is symmetric with respect to the center of the full period Tpwm of the pulse width modulation signal PWS1. For example, in FIG. 4A, a high-level period T1 of the pulse width modulation signal PWS1 during the first half period is the same as a high-level period T2 of the pulse width modulation signal PWS1 during the second half period. Accordingly in FIG. 4A, a difference TD between the high-level periods T1 and T2 is expressed by TD=T2−T1=0.

As illustrated in FIG. 4B, a full period Tdsm of the multi-bit quantization signal MQS2 corresponds to a half period of the ramp signal RAMP, and a half period Tpwm/2 of the pulse width modulation signal PWS2. The half period Tdsm is generated from the center to an edge of the full period Tpwm of the pulse width modulation signal PWS2. The multi-bit quantization signal MQS2 in a first half period of the pulse width modulation signal PWS2 is different from that in a second half period of the pulse width modulation signal PWS2. The multi-bit quantization signal MQS2 in the first half period is referred to as a first signal M0, and the multi-bit quantization signal MQS2 in the second half period is referred to as a second signal M1. The comparator 220 compares the first signal M0 with the ramp signal RAMP during the first half period of the pulse width modulation signal PWS2 to generate the pulse width modulation signal PWS2 during the first half period. The comparator 220 compares the second signal M1 with the ramp signal RAMP during the second half period of the pulse width modulation signal PWS2 to generate the pulse width modulation signal PWS2 during the second half period.

When the first signal M0 and the second signal M1 are different from each other with different levels, the pulse width modulation signal PWS2 is an asymmetric pulse signal that is asymmetric with respect to the center of period of the pulse width modulation signal PWS2.

FIG. 4B illustrates an example where a respective level of the second signal M1 is higher than the respective level of the first signal M0. For example, the high-level period T2 of the pulse width modulation signal PWS2 during the second half period is greater than the high-level period T1 of the pulse width modulation signal PWS2 during the first half period. The difference between the high-level periods T1 and T2 is expressed by TD=T2−T1. The difference TD is not zero except when the level of the first signal M0 is the same as the level of the second signal M1.

Referring FIGS. 4A and 4B, the second clock signal CLK2, which is output to the PWM 200 of FIG. 1, has a frequency in FIG. 4A where the PWM 200 is a symmetric type, which is twice as high as a frequency in FIG. 4B, where the PWM 200 is an asymmetric type. When the PWM 200 is a symmetric type as illustrated in FIG. 4A, the frequency of the second clock signal CLK2 may correspond to equation 2 as follows:

OSR*QL*2*SR [Equation 2],

where OSR is the oversampling rate of the over-sampler 20, QL is the quantization level of the DSM 100, and SR is a sampling frequency (i.e., the frequency at which the digital signal DS is sampled from an analog signal). When the PWM 200 is an asymmetric type as illustrated in FIG. 4B, the frequency of the second clock signal CLK2 may corresponds to equation 3 as follows:

OSR*QL*1*SR [Equation 3].

In addition, when the PWM 200 is a symmetric type as illustrated in FIG. 4A, the PWM 200 modulates one sample of the multi-bit quantization signal MQS during the full period of the ramp signal RAMP. When the PWM 200 is an asymmetric type as illustrated in FIG. 4B, the PWM 200 asymmetrically modulates two samples of the multi-bit quantization signal MQS during the full period of the ramp signal RAMP. Therefore, the frequency of the PWM 200 of the asymmetric type may be half as high as the frequency of the PWM 200 of the symmetric type. However, when the PWM 200 is an asymmetric type as illustrated in FIG. 4B, an asymmetric error may be generated. The asymmetric error may be corrected by an error correction circuit.

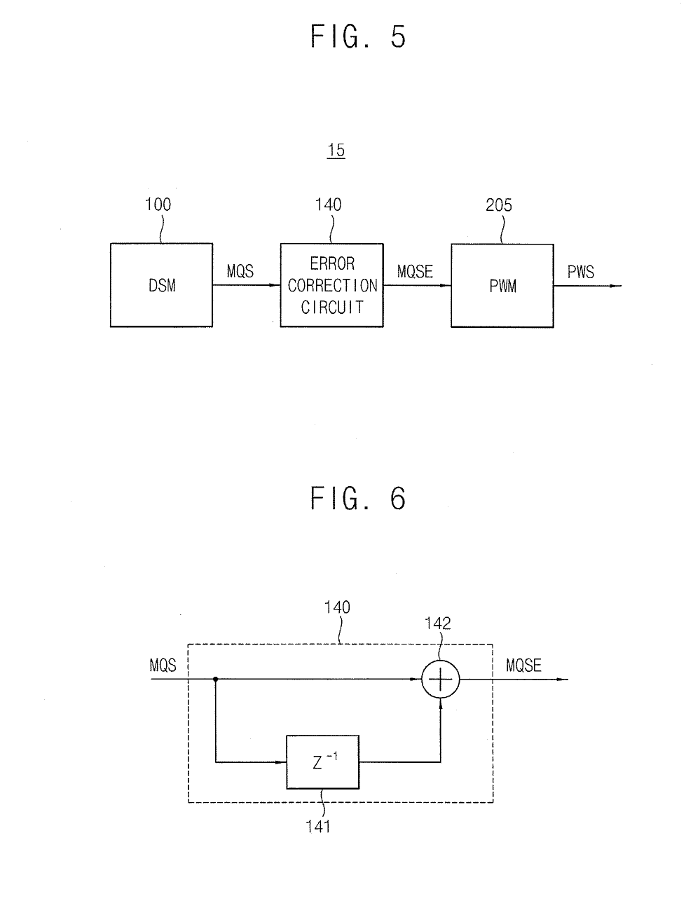

FIG. 5 is a block diagram illustrating an audio DAC according to an exemplary embodiment of the inventive concept. In FIG. 5, the output unit 300 of FIG. 1 is not illustrated and the PWM 200 is an asymmetric type. Referring to FIG. 5, an audio DAC 15 includes the DSM 100, an error correction circuit 140 and a PWM 205.

An ideal transfer function of the error correction circuit 140 for correcting the asymmetric error E2 generated by the PWM 205 may be expressed by equation 4 as follows:

EC(z)=1{J+E2(z)} [Equation 2],

where J is a constant (e.g., a real number such as 0, 1, 0.5, etc.).

When J=K (e.g., a gain factor)=H(z) (e.g., a transfer function of the asymmetric-type PWM 205 having no errors), K+E2(z) becomes the transfer function of the asymmetric-type PWM 205 having an asymmetric error. When this occurs, the transfer function EC(z) of the error correction circuit 140 is the inverse of the transfer function K+E2(z) of the asymmetric-type PWM 205 having the asymmetric error.

Alternatively, when J=0, EC(z)=1/E2(z), and therefore, the transfer function EC(z) of the error correction circuit 140 is the inverse of the transfer function E2(z) of the asymmetric error. Accordingly, the error correction circuit 140 may be embodied to have a transfer function corresponding to the inverse of the transfer function of the asymmetric type PWM 205 or the transfer function E2(z) of the asymmetric error.

The error correction circuit 140 operates through an open loop path between the DSM 100 and the PWM 205 such that the error correction circuit 140 does not influence and/or is not influenced by the transfer characteristics of the feedback circuit of the DSM 100. Accordingly, the error correction circuit 140 should not affect system stability and the characteristics of the DSM 100. When E2(z) is modeled to have a transfer function of (1−Z⁻¹), the error correction circuit 140 is modeled to have a transfer function of 1/(1−Z⁻¹).

FIG. 6 is a block diagram illustrating an example of the error correction circuit of FIG. 5 according to an exemplary embodiment of the inventive concept. Referring to FIG. 6, in at least one exemplary embodiment of the inventive concept, the error correction circuit 140 may be implemented as a low pass filter to have a transfer function of (1+Z⁻¹). For example, the error correction circuit 140 may include a delayer 141 and an adder 142. The delayer 141 delays the multi-bit quantization signal MQS. The adder 142 adds the multi-bit quantization signal MQS and an output of the delayer 141.

When bit truncation is not performed on the multi-bit quantization signal MQS, the number of bits in an output signal of the error correction circuit 140 (e.g., the error-corrected quantization signal MQSE) may be continuously integrated when the error correction circuit 140 is implemented to have the inverse of (1−Z⁻¹), i.e., 1/(1−Z⁻¹), as the transfer function. The number of bits in the input signal of the PWM 205 may be continuously increased and may go beyond the normal range of the ramp signal RAMP used for pulse width modulation.

When the normal range of the ramp signal RAMP is set to a large value, an operating frequency required for pulse width modulation is increased, which can make the implementation of the hardware difficult. Accordingly, the error correction circuit 140 may be implemented as a low-pass filter instead of an integrator by adding two adjacent signals (e.g., a current signal and a previous signal).

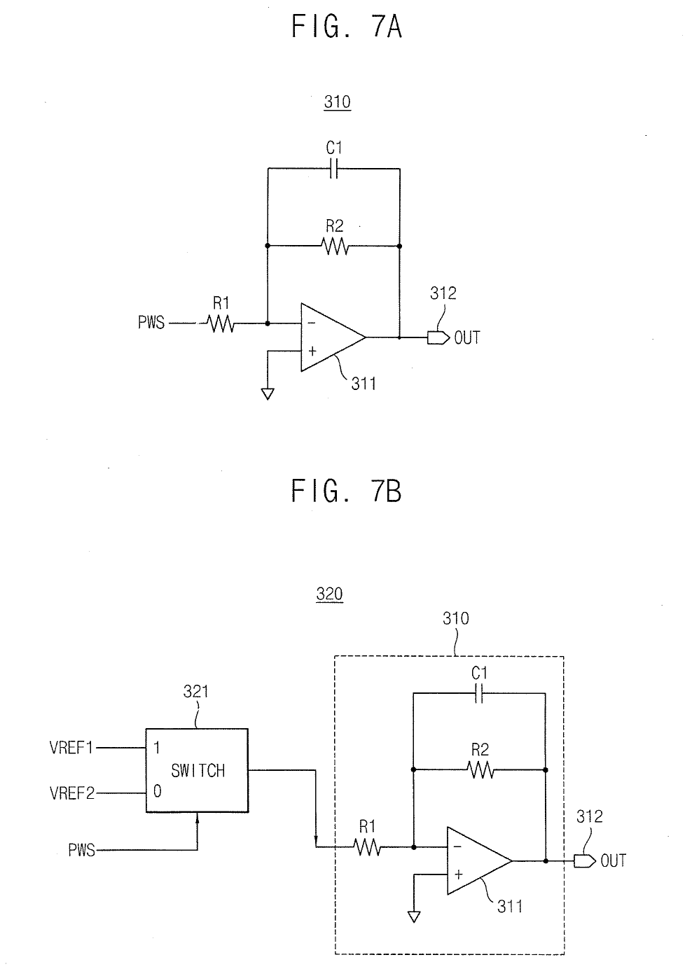

FIG. 7A is a circuit diagram illustrating an example of the output unit in FIG. 1 according to an exemplary embodiment of the inventive concept. Referring to FIG. 7A, an output unit 310 includes an operational amplifier 311, resistors R1 and R2 and a capacitor C1. The pulse width modulation signal PWS is applied to a first (inverting) input terminal of the operational amplifier 311 through the resistor R1. A second (non-inverting) input terminal of the operational amplifier 311 is connected to ground. The first input terminal and the output terminal of the operational amplifier 311 are connected to each other through the resistor R2 and the capacitor C1. The resistor R2 is connected to the capacitor C1 in parallel. Accordingly, the operational amplifier 311, the resistors R1 and R2 and the capacitor C1 operate as a low-pass filter (i.e., an analog filter) to generate an analog output signal OUT with an analog value. The analog output signal may have reduced high-frequency noise, according to the bit of the single bit pulse width modulation signal PWS.

FIG. 7B is a circuit diagram illustrating an example of the output unit in FIG. 1 according to an exemplary embodiment of the inventive concept. Referring to FIG. 7B, an output unit 320 includes an analog filter 310 and a switching circuit 321. The switching circuit 321 selectively connects a first reference voltage VREF 1 or a second reference voltage VREF2 to the analog filter 310 according to the logic level of the pulse width modulation signal PWS. For example, when the pulse width modulation signal PWS is a logic high level, the first reference voltage VREF1 is applied to the first (inverting) input terminal of the operational amplifier 311 through the first resistor R1. For example, when the pulse width modulation signal PWS is a logic low level, the second reference voltage VREF2 is applied to the first (inverting) input terminal of the operational amplifier 311 through the first resistor R1.

In FIG. 7B, the switching circuit 321 is illustrated as an example. However, a different circuit element performing the same operation as the switching circuit 321 may replace the switching circuit 321. For example, a multiplexer may replace the switching circuit 321. When a multiplexer is included instead of the switching circuit 321, the pulse width modulation signal PWS is applied to the multiplexer as a control input, and the multiplexer may selectively connect the first reference voltage VREF1 or the second reference voltage VREF2 to the analog filter 310 in response to the pulse width modulation signal PWS.

When the output unit 320 is implemented with the switching circuit 321 as illustrated in FIG. 7B, noise generated by the pulse width modulation signal PWS when the pulse width modulation signal PWS is directly applied through the resistor R1 may be minimized. When the pulse width modulation signal PWS includes noise, the noise generated by the pulse width modulation signal PWS may be minimized because the first reference voltage VREF1 or the second reference voltage VREF2 is applied to the first (inverting) input terminal of the operational amplifier 311.

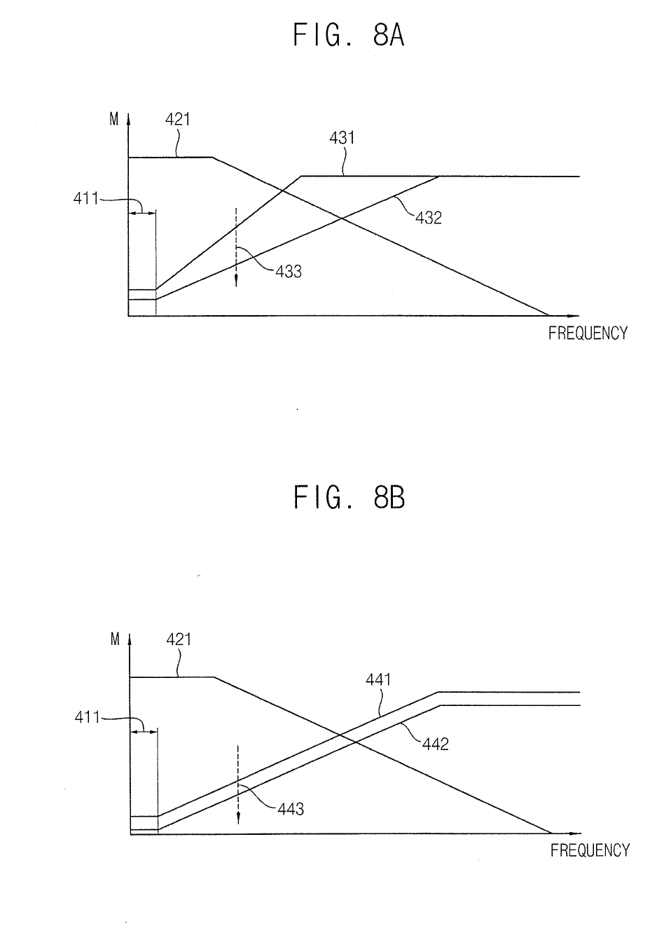

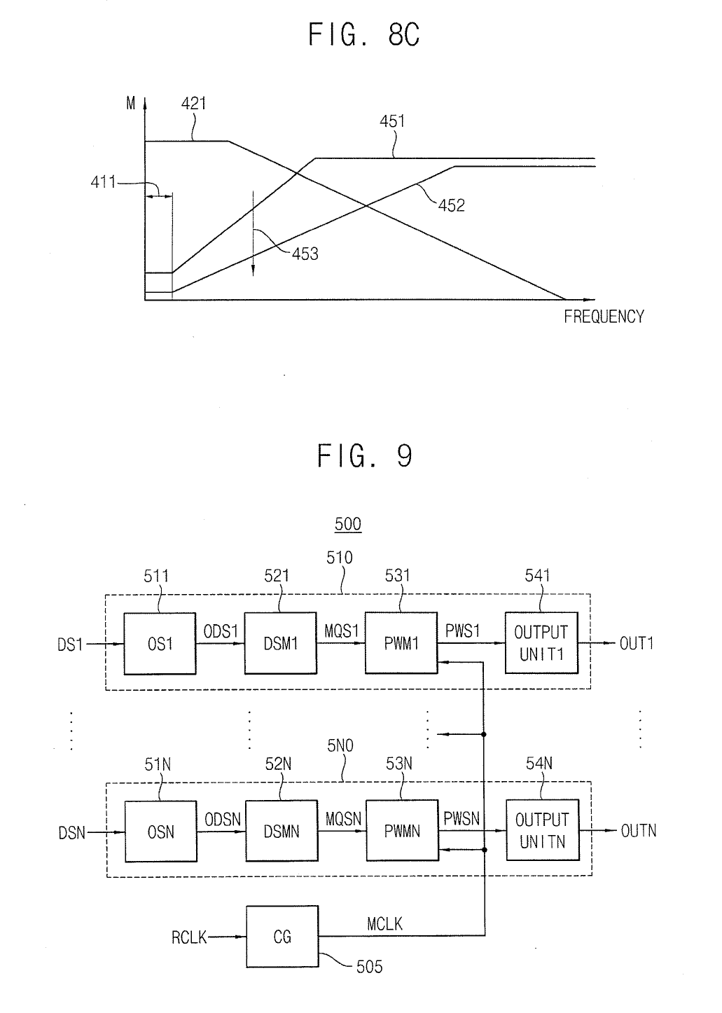

FIGS. 8A through 8C are diagrams for explaining concepts of the exemplary embodiments. Referring to FIG. 1, a resolution of the DSM 100 may be determined based on OSR and the bit number of the quantization (i.e., the quantization level).

FIG. 8A is a graph illustrating an exemplary relationship between OSR and a transfer function. In FIG. 8A, a reference numeral 411 represents an audio frequency zone, a reference numeral 421 represents a frequency response characteristic of a low-pass filter, a reference numeral 431 represents a transfer function before increasing an OSR, and a reference numeral 432 represents a transfer function after increasing the OSR. Referring to FIG. 8A, when the OSR is increased, the transfer function shifts to a direction as indicated by arrow 433. Accordingly, when the OSR is increased, the quantization noise shifts to the high-frequency zone and the noise near the audio frequency zone 411 may be decreased. Therefore, the quantization noise may be reduced without adopting a switched capacitor filter.

FIG. 8B is a graph illustrating an exemplary relationship between a quantization level and a transfer function. In FIG. 8B, a reference numeral 411 represents an audio frequency zone, a reference numeral 421 represents a frequency response characteristic of a low-pass filter, a reference numeral 441 represents a transfer function before increasing the quantization level, and a reference numeral 442 represents a transfer function after increasing the quantization level. Referring to FIG. 8B, when the quantization level is increased, the transfer function shifts to a direction as indicated by arrow 443. Accordingly, the quantization noise may be reduced.

FIG. 8C is a graph illustrating a relationship between OSR, a quantization level, and a transfer function. In FIG. 8C, a reference numeral 411 represents an audio frequency zone, a reference numeral 421 represents a frequency response characteristic of a low-pass filter, a reference numeral 451 represents a transfer function before increasing the OSR and the quantization level, and a reference numeral 452 represents a transfer function after increasing the OSR and the quantization level. Referring to FIG. 8C, when the OSR and the quantization level are simultaneously increased, the transfer function shifts to a direction as indicated by arrow 453. Accordingly, when the OSR and the quantization level are increased, the quantization noise shifts to the high-frequency zone and the noise near the audio frequency zone 411 may be decreased. Therefore, the quantization noise may be reduced without adopting a switched capacitor filter.

Accordingly, the quantization noise may be sufficiently reduced without adopting a switched capacitor filter by simultaneously increasing the OSR and the quantization level according to at least one exemplary embodiment of the inventive concept. Therefore, power consumption and chip size may be sufficiently reduced. In addition, an operating frequency of the PWM 200 may be much higher than an operating frequency of the DSM 100 because the PWM operates with increased frequency for reducing the quantization noise.

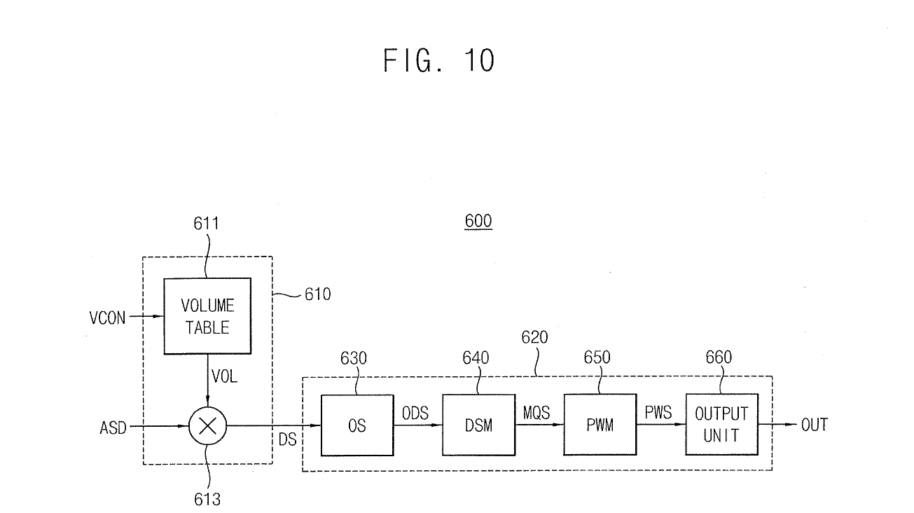

FIG. 9 is a block diagram illustrating a multi-channel audio DAC according to an exemplary embodiment of the inventive concept. Referring to FIG. 9, a multi-channel audio DAC 500 includes a plurality of channels 510˜5N0 and a clock generator (CG) 505. Each of the plurality of channels 510˜5N0 includes each of over-samplers 511˜51N, each of DSMs 521˜52N, each of PWMs 531˜53N and each of output units 541˜54N. Each of the plurality of channels 510˜5N0 converts each of digital signals DS1˜DSN to each of analog output signals OUT1˜OUTN. When each of the PWMs 531˜53N is a symmetric type in FIG. 9, configuration of FIG. 9 is adopted without being modified. When each of the PWMs 531˜53N is an asymmetric type, a corresponding error correction circuit may be inserted between each of the DSMs 521˜52N and each of the PWMs 531˜53N as illustrated in FIG. 5, and may perform error correction. In addition, each of the output units 541˜54N may employ the output unit 310 of FIG. 7A or the output unit 320 of FIG. 7B.

The PWMs 531˜53N share the one clock generator 505. The clock generator 505 multiplies a reference clock signal RCLK and provides the multiplied clock signal MCLK to each of the PWMs 531˜53N. Therefore, power consumption and chip size may be sufficiently reduced by sharing one clock generator 505 as illustrated in FIG. 9 in systems that employ multiple channels, such as digital televisions and DVDs which may employ 5.1 channel or 7.1 channel. When six channels are employed and switched capacitor filters are employed, the switched capacitor filters are required for each channel, and thus six switched capacitor filters are required. Accordingly, power consumption and the chip size may be sufficiently increased, and switching noise due to the switched capacitor filter may be increased.

FIG. 10 is a block diagram illustrating an audio processing apparatus according to an exemplary embodiment of the inventive concept. Referring to FIG. 10, an audio processing apparatus 600 includes a volume control unit 610 and an audio DAC 620. The audio DAC 620 includes an over-sampler 630, a DSM 640, a PWM 650 and an output unit 660.

The volume control unit 610 includes a volume table 610 and a multiplier 613. The volume table 611 outputs a volume value VOL in response to a volume control signal VCON. The volume value VOL is a level control value for controlling the level of audio source data ASD. The audio source data ASD may include pulse code modulation (PCM) data.

The volume table 611 stores a table for mapping the volume control signal VCON to the volume value VOL. When a user of the audio processing apparatus 600 adjusts the volume of an audio signal, the volume control signal VCON corresponds to the user's adjustment. The volume control signal VCON may be a digital code including a plurality of bits. For example, when the volume control signal VCON includes 4 bits, volume may be controlled at 16 levels.

The multiplier 613 multiplies the audio source data ASD by the volume value VOL and outputs volume-controlled digital signal DS. For example, the multiplier 613 amplifies or attenuates the level of the audio source data ASD according to the volume value VOL. When the volume value VOL is greater than 1 (0 dB), the level of the audio source data ASD is amplified. When the volume value VOL is less than 1 (0 dB), the level of the audio source data ASD is attenuated. A volume value of 1 (0 dB) may be interpreted as a maximum volume value.

The audio source data ASD may be obtained by performing PCM on a signal resulting from sampling an analog audio signal at a predetermined sampling rate (e.g., 48 kHz). The audio source data ASD may be include a plurality of bits, e.g. 16 bits, 20 bits, etc.

The over-sampler 630 over-samples the digital signal DS from the volume control unit 610 at a frequency higher than the audio sampling frequency. The over-sampler frequency may be, for example, 16, 32 or 64 times the audio sampling frequency (e.g., 48 kHz).

The PWM 650 may be a symmetric type or an asymmetric type as described above. When the PWM 650 is an asymmetric type, an error correction circuit may be inserted between the DSM 640 and the PWM 650 as illustrated in FIG. 5.

The output unit 660 may employ the output unit 310 of FIG. 7A or the output unit 320 of FIG. 7B, and filters the pulse width modulation signal PWS to output the analog output signal OUT, i.e., an analog audio signal.

As mentioned above, the quantization noise may be reduced by increasing the OSR and the quantization level, thereby operating the PWM at a higher frequency without adopting the switched-capacitor filter according to at least one embodiment of the inventive concept. Accordingly, power consumption and chip size may be sufficiently reduced. At least one exemplary embodiment of the inventive concept may be applied to digital audio devices that employ multi-channels.

Having described exemplary embodiments of the inventive concept, it should be understood that various changes, substitutions and alterations can be made therein without departing from the scope of the present inventive concept. Accordingly, all such modifications are intended to be included within the scope of the present inventive concept.

What is claimed is:

1. An audio digital to analog converter (DAC), comprising:
a delta/sigma modulator (DSM) configured to delta-sigma modulate an over-sampled digital signal to generate a multi-bit quantization signal;
a pulse width modulator (PWM) configured to pulse width modulate the multi-bit quantization signal to generate a single-bit pulse width modulation signal; and
an output unit including an analog filter configured to low-pass filter the single-bit pulse width modulation signal to generate an analog output signal.

2. The audio DAC of claim 1, wherein the PWM is a symmetric-type PWM.

3. The audio DAC of claim 1, wherein the PWM is an asymmetric-type PWM.

4. The audio DAC of claim 3, further comprising an error correction circuit, connected between the DSM and the PWM, and configured to correct errors generated by the PWM.

5. The audio DAC of claim 4, wherein the error correction circuit is connected in an open loop between the DSM and the PWM.

6. The audio DAC of claim 4, wherein the error correction circuit comprises:
a delayer delaying the multi-bit quantization signal; and
an adder adding the multi-bit quantization signal and an output of the delayer.

7. The audio DAC of claim 1, wherein the output unit further comprises:
a switching circuit configured to selectively connect a first reference voltage and a second reference voltage to the analog filter in response to the single-bit pulse width modulation signal.

8. The audio DAC of claim 1, further comprising:
a clock generator configured to generate a first clock signal and a second clock signal having a higher frequency than a frequency of the first clock signal,
wherein the first clock signal is provided to the DSM, and the second clock signal is provided to the PWM.

9. The audio DAC of claim 8, wherein the frequency of the second clock signal is K times as high as the frequency of the first clock signal, and K is a positive equal to or greater than two.

10. The audio DAC of claim 8, wherein the PWM comprises:
a ramp signal generator configured to generate a triangular ramp signal swinging between a first peak value and a second peak value based on the second clock signal;
a comparator configured to compare the multi-bit quantization signal with the ramp signal to provide the pulse width modulation signal having a pulse width varying according to a level of the multi-bit quantization signal, in synchronization with the second clock signal.

11. The audio DAC of claim 1, further comprising:
an over-sampler that over-samples a digital input signal to generate the over-sampled digital signal.

12. The audio DAC of claim 11, wherein the DSM comprises:
a subtracter that subtracts the multi-bit quantization signal from the over-sampled digital signal;
a loop filter that filters an output signal of the subtracter; and
a quantizer that quantizes an output signal of the loop filter to generate the multi-bit quantization signal.

13. The audio DAC of claim 1, wherein an operating frequency of the PWM is higher than an operating frequency of the DSM.

14. A multi-channel audio digital-to-analog converter (DAC), comprising:
a plurality of channels, each converting a corresponding digital input signal to a corresponding analog output signal; and
a clock generator configured to multiply a reference clock signal to generate a multiplied clock signal and output the multiplied clock to each pulse width modulator PWM included in each of the channels,
wherein each of the channels comprises:
a delta sigma modulator DSM configured to quantize the corresponding digital input signal which is over-sampled to generate a multi-bit quantization signal;
a PWM configured to pulse width modulate the corresponding multi-bit quantization signal to generate a single-bit pulse width modulation signal; and
an output unit including an analog filter configured to low-pass filter the corresponding single-bit pulse width modulation signal to generate the corresponding analog output signal.

15. The multi-channel audio DAC of claim 14, wherein the clock generator is shared by the plurality of channels.

16. The multi-channel audio DAC of claim 14, wherein the PWM is one of a symmetric-type or an asymmetric-type PWM.

17. The multi-channel audio DAC of claim 16, wherein when the PWM is the asymmetric-type PWM, the multi-channel audio DAC further comprises an error correction circuit connected in an open loop between the DSM and the PWM, and configured to correct errors generated by the PWM.

18. The multi-channel audio DAC of claim 17, wherein the error correction circuit is configured to be isolated from being influenced by or influencing transfer characteristics of a feedback circuit of the DSM.

19. An audio processing apparatus, comprising:
a volume control unit configured to volume-control audio source data to generate a digital data in response to a volume control signal; and
an audio digital to analog converter (DAC) configured to over-sample the digital data, and configured to convert the over-sampled digital data to an analog output signal,
wherein the audio DAC comprises:
a delta/sigma modulator (DSM) configured to delta-sigma modulate the over-sampled digital data to generate a multi-bit quantization signal;
a pulse width modulator (PWM) configured to pulse width modulate the multi-bit quantization signal to generate a single-bit pulse width modulation signal; and
an output unit including an analog filter configured to low-pass filter the single-bit pulse width modulation signal to generate the analog output signal.

20. The audio processing apparatus of claim 19, wherein the volume control unit comprises:
a volume table outputting a volume value in response to the volume control signal; and
a multiplier that multiplies the audio source data by the volume value to generate the digital data.
